(19) United States
(12) Patent Application Publication
(10) Pub. No.: US 2025/0391793 A1
(43) Pub. Date: Dec. 25, 2025

(54) SEMICONDUCTOR DEVICE AND METHOD OF MANUFACTURING SEMICONDUTOR DEVICE

(71) Applicant: FUJI ELECTRIC CO., LTD., Kawasaki-shi (JP)

(72) Inventors: Kohichi HASHIMOTO, Matsumoto-city (JP); Shunsuke TANAKA, Matsumoto-city (JP); Tomo ODASHIMA, Matsumoto-city (JP)

(73) Assignee: FUJI ELECTRIC CO., LTD., Kawasaki-shi (JP)

(21) Appl. No.: 19/224,267

(22) Filed: May 30, 2025

(30) Foreign Application Priority Data
Jun. 19, 2024 (JP) 2024-098657

(51) Int. Cl. H01L 23/00; C23C 18/18; C23C 18/32

(52) U.S. Cl. CPC H01L 24/03; H01L 24/05; C23C 18/1889; C23C 18/32; H01L 2224/031; H01L 2224/03464; H01L 2224/05124; H01L 2224/05655

(57) ABSTRACT

A method of manufacturing a semiconductor device, including: preparing a semiconductor substrate; forming a metal electrode including a first portion and a second portion on the semiconductor substrate, the first portion having a surface layer and an oxide film; forming an insulating film to cover the metal electrode; forming an opening penetrating through the insulating film in a depth direction, to thereby expose the first portion; performing a pre-treatment of removing the oxide film; and performing an electroless plating treatment to form a plating film on the first portion. The second portion is covered with the insulating film. The pre-treatment includes etching the first portion to remove the oxide film together with the surface layer, so as to cause the first portion to be thinner than the second portion. The surface layer has a maximum thickness that is within a range of thickness variation of the oxide film.

### CROSS REFERENCE TO RELATED APPLICATIONS

This application is based upon and claims the benefit of priority of the prior Japanese Patent Application No. 2024-098657, filed on Jun. 19, 2024, the entire contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Japanese Laid-Open Patent Publication No. 2008-85368 describes removal of an Al oxide film on a surface of an Al electrode by acid etching before electroless Ni/Au plating using a zincate method. International Publication No. WO2019/107529 and Japanese Laid-Open Patent Publication No. 2019-099864 describe etching conditions for roughening a surface of an Al-containing base material to provide excellent bonding strength with resin. International Publication No. WO2018/150971 describes etching conditions for forming multiple recesses on a surface of an electroless plating treatment layer. Japanese Laid-Open Patent Publication No. 2011-222898 and Japanese Laid-Open Patent Publication No. 2016-152317 describe a technology for protecting a semiconductor wafer, a surface thereof that is not to be electroless plated being protected with tape.

### SUMMARY OF THE INVENTION

According to an embodiment of the present disclosure, a method of manufacturing a semiconductor device, the method includes: preparing a semiconductor substrate having a first main surface and a second main surface opposite to each other; forming a metal electrode on the first main surface of the semiconductor substrate, the metal electrode having a first portion and a second portion, the first portion having a surface layer and an oxide film formed on the surface layer; forming an insulating film to cover the metal electrode; forming an opening penetrating through the insulating film in a depth direction, to thereby expose the first portion of the metal electrode; performing a pre-treatment of removing the oxide film of the first portion; and performing an electroless plating treatment after the pre-treatment, to thereby form a plating film on the first portion. The second portion is covered with the insulating film. The pre-treatment includes etching the first portion by a predetermined etching amount, to thereby remove the oxide film together with the surface layer, so as to cause a thickness of the first portion to be thinner than a thickness of the second portion. The surface layer of the first portion has a maximum thickness that is within a range of thickness variation of the oxide film.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1A is a plan view depicting an example of a layout of a semiconductor device according to an embodiment, as viewed from a front surface of a semiconductor substrate thereof.

FIG. 1B is a plan view depicting an example of a layout of the semiconductor device according to the embodiment, as viewed from the front surface of the semiconductor substrate thereof.

FIG. 2 is a cross-sectional view taken along a cutting line A-A′ in FIGS. 1A and 1B.

FIG. 3 is a flowchart depicting an outline of a method for manufacturing the semiconductor device according to the embodiment.

FIG. 4 is a flowchart depicting an outline of a process at step S11 in FIG. 3.

FIG. 5 is a graph depicting an etching amount of an Al electrode by a pre-treatment for an electroless plating treatment in an example.

FIG. 6 is a graph depicting the etching amount of the Al electrode by the pre-treatment for the electroless plating treatment in a comparison example.

FIG. 7 is a graph depicting results of an experiment on a relationship between pre-treatment conditions of the electroless plating treatment and total etching amount of the Al electrode.

### DETAILED DESCRIPTION OF THE INVENTION

Japanese Laid-Open Patent Publication No. 2008-85368 has a risk that zincating proceeds with an Al oxide film remaining locally on a surface of an Al electrode, whereby adhesion between the Al electrode and a plating film decreases and peeling of the plating film from the surface of the Al electrode occurs when wire bonding is performed on the surface of the Al electrode via the plating film.

An outline of an embodiment of the present disclosure is described. (1) A method of manufacturing a semiconductor device according to an embodiment of the present disclosure is as follows. A first process of forming a metal electrode on a first surface of a semiconductor substrate is performed. A second process of forming an insulating film at the first surface of the semiconductor substrate is performed, the insulating film covering the metal electrode. A third process of forming an opening penetrating through the insulating film in a depth direction is performed, the opening exposing a first portion of the metal electrode. A pre-treatment of removing an oxide film on the surface of the first portion is performed. A plating treatment of forming a plating film on the surface of the first portion by an electroless plating treatment is performed after the pre-treatment. In the pre-treatment, the first portion is etched a predetermined amount thereby reducing a thickness of the first portion to be thinner than a thickness of a second portion of the metal electrode covered by the insulating film, and the oxide film is removed together with a surface layer of the first portion by a maximum thickness within a range of thickness variation of the oxide film.

According to the above disclosure, a clean surface can be exposed in an entire area of the surface of the first portion of the metal electrode and a plating film with high adhesion can be formed on the entire surface of the first portion of the metal electrode. Therefore, peeling of the plating film caused by residual Al oxide film on the surface of the metal electrode may can suppressed, thereby improving reliability of the semiconductor device.

(2) Further, in the method of manufacturing a semiconductor device according to the present disclosure, in (1) above, the pre-treatment includes performing a fourth process of etching the oxide film by an etching solution and after the fourth process, performing a fifth process of etching the oxide film by a zincate solution and precipitating a metal on the surface of the first portion, the metal having a smaller ionization tendency than a metal contained in the metal electrode. The predetermined etching amount may be a sum of an etching amount of the first portion by the etching solution and an etching amount of the first portion by the zincate solution.

According to the above disclosure, by etching the metal electrode using the zincate solution, occurrence of spikes in the metal electrode, at the surface thereof, is suppressed. This suppresses peeling of the plating film caused by spikes at an interface between the metal electrode and the plating film, thereby, further improving the reliability of the semiconductor device.

(3) Further, in the method of manufacturing a semiconductor device according to the present disclosure, in (2) above, the etching amount of the first portion by the etching solution may be equal to or greater than the etching amount of the first portion by the zincate solution.

According to the disclosure above, zincate solution conditions for the fifth process can be provided a margin and the occurrence of spikes at the surface of the Al electrode due to the fifth process being performed excessively can be suppressed.

(4) Further, in the method of manufacturing a semiconductor device according to the present disclosure, in any one of (1) to (3) above, the predetermined etching amount may be 0.3 μm or more but not more than 0.6 μm.

According to the disclosure above, desired adhesion between the metal electrode and the plating film is obtained and appearance defects of the surface of the plating film can be suppressed.

(5) Further, in the method of manufacturing a semiconductor device according to the present disclosure, in (4) above, the predetermined etching amount may be 0.4 μm or more.

According to the disclosure above, adhesion between the metal electrode and the plating film can be further improved.

(6) Further, in the method of manufacturing a semiconductor device according to the present disclosure, in (5) above, the predetermined etching amount may be 0.45 μm or more.

According to the disclosure above, adhesion between the metal electrode and the plating film can be further improved.

(7) Further, in the method of manufacturing a semiconductor device according to the present disclosure, in any one of (1) to (6) above, in the first process, an aluminum film or an aluminum alloy film is formed as the metal electrode and in the plating process, a nickel-plating film in contact with at least the first portion may be formed as the plating film.

According to the disclosure above, heat dissipation of the semiconductor substrate (semiconductor chip) can be increased.

(8) A semiconductor device according to the present disclosure is as follows. A metal electrode is provided on a first surface of a semiconductor substrate. An insulating film is provided on an outermost surface of the first main surface of the semiconductor substrate. The insulating film covers a second portion of the metal electrode. The first portion of the metal electrode is exposed in an opening that penetrates through the insulating film in a depth direction. A plating film is provided on the surface of the first portion. At the first portion, the metal electrode is recessed closer to a second main surface of the semiconductor substrate than at the second portion. A difference obtained by subtracting a thickness of the first portion from a thickness of the second portion is 0.3 μm or more but not more than 0.6 μm.

According to the disclosure above, desired adhesion between the metal electrode and the plating film is obtained and appearance defects of the surface of the plating film can be suppressed.

(9) Further, in the semiconductor device according to the present disclosure, in (8) above, the difference may be 0.4 μm or more.

According to the above disclosure, the adhesion between the metal electrode and the plating film can be further improved.

(10) Further, in the semiconductor device according to the present disclosure, in (9) above, the difference may be 0.45 μm or more.

According to the disclosure above, adhesion between the metal electrode and the plating film can be further improved.

(11) Further, in the semiconductor device according to the present disclosure, in any one of (8) to (10) above, the metal electrode is an aluminum film or an aluminum alloy film and the plating film may have a nickel-plating film in contact with at least the first portion.

According to the disclosure above, heat dissipation of the semiconductor substrate (semiconductor chip) can be increased.

The findings underlying the present disclosure are discussed. In general, in a case of forming a nickel (Ni) plating film on a surface of an electrode containing aluminum (Al) (hereinafter referred to as an Al electrode) by an electroless plating treatment, a zincate treatment is performed on the surface of the Al electrode as a pre-treatment for the electroless plating treatment. In the zincate treatment, in conjunction with dissolving an Al oxide film on the surface of the Al electrode by a zincate solution, a Zn film having higher adhesion to Ni than Al is precipitated on the surface of the Al electrode by a substitution reaction between Al in the Al electrode and zinc (Zn) in the zincate solution.

The Zn film is formed on the surface of the Al electrode, thereby suppressing surface oxidation of the Al electrode and improving adhesion between the Al electrode and the Ni plating film.

However, in a general electroless plating treatment and the pre-treatment thereof, there is a risk that the plating film may peel off from the surface of the Al electrode during wire bonding at the surface of the Al electrode via the plating film in a subsequent assembly process (mounting process of a semiconductor chip). The electroless plating treatment and the pre-treatment thereof are successive treatments by automated plating equipment and are, for example, performed in series (on a line) under the same conditions (batch processing) with respect to all semiconductor wafers passing through the line during a predetermined period. This causes concerns about reliability of all semiconductor chips (semiconductor chips of the same lot) fabricated during the same period as a semiconductor chip from which the plating film peeled off.

One of factor causing the plating film to peel off from the surface of the Al electrode is that the Al oxide film on the surface of the Al electrode is so thick locally that the Al oxide film on the surface of the Al electrode cannot be completely removed under generally recommended conditions for the zincate treatment, whereby the zincate treatment is performed in a state in which the Al oxide film remains locally on the surface of the Al electrode, thereby reducing the adhesion between the Al electrode and the Ni plating film. The Al oxide film on the surface of the Al electrode is a stacked film of a thermal oxide film formed by thermal oxidation of the surface of the Al electrode due to a temperature distribution in manufacturing processing, and a natural oxide film naturally formed on the surface of the Al electrode during transport of the semiconductor wafer or during the manufacturing processing at room temperature.

In a portion where the Al oxide film on the surface of the Al electrode is removed, a clean surface of the Al electrode is exposed, the zincate treatment proceeds normally, and a Zn film is precipitated on the surface of the Al electrode. Thus, during the electroless plating treatment, Zn in the Zn film is substituted with Ni in the plating solution thereby precipitating an Ni plating film on the surface of the Al electrode. On the other hand, in a portion where the Al oxide film remains locally on the surface of the Al electrode, the zincate solution does not contact the surface of the Al electrode and thus, the substitution reaction between Al and Zn does not occur. In a portion where the Al oxide film remains locally on the surface of the Al electrode, the Zn film is not formed and thus, the Ni in the plating solution does not precipitate and conversely, the Al electrode is dissolved by the plating solution.

In the portion where the Al electrode is dissolved, a long and narrow groove in the depth direction called a spike is generated in the Al electrode, at the surface thereof. The spike at the surface of the Al electrode is filled with a plating film having low adhesion to the Al electrode due to autocatalytic reaction of Ni in the plating solution, or the spike becomes a void between the Al electrode and the plating film. When respective sides of multiple spikes generated in a dense manner are connected to each other, the adhesion between the Al electrode and the plating film is low at the connection point of the spikes and the plating film peels off from the surface of the Al electrode due to tensile stress received from a bonding wire. In particular, in power devices that handle high voltages and large currents, semiconductor chips with improved heat dissipation by forming a plating film on the surface of the Al electrode are often used and adhesion of the plating film is required.

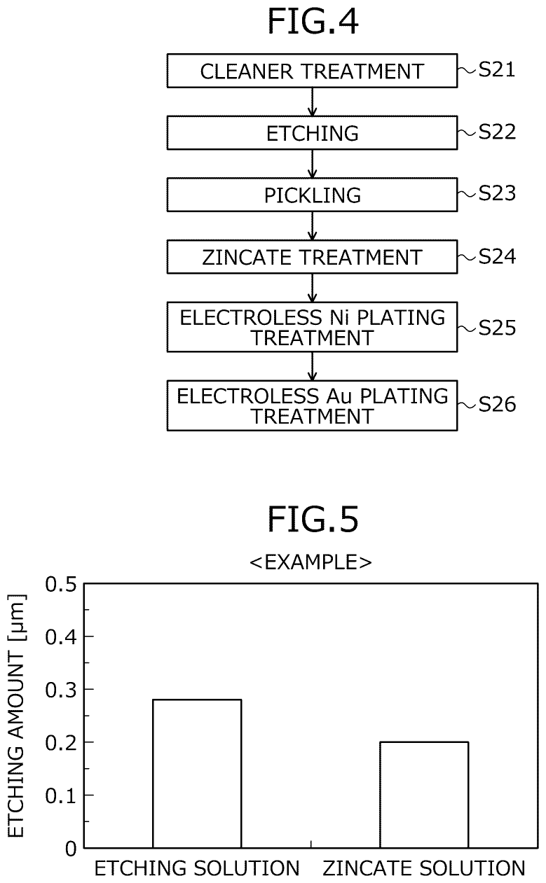

In a pre-treatment for an electroless Ni plating treatment (steps S21 to S24 in FIG. 4 described later), the inventors of the present invention paid attention to the processes at steps S22 and S24 (etching the surface of the Al electrode, and zincate treatment on the surface of the Al electrode) which has an effect of dissolving the oxide film. As a result of a preliminary experiment described later (see FIG. 7), it was found that when the total etching amount of the Al electrode is set to 0.3 μm or more by combining an etching amount by an etching solution in etching at step S22 and an etching amount by the zincate solution in the zincate treatment at step S24, the entire plated surface of the Al electrode is covered with the Zn film thereby improving the adhesion between the Al electrode and the plating film. The present disclosure is made based on such findings.

Problems to be solved in this embodiment include improving reliability of a semiconductor device (semiconductor chip) by improving the adhesion between the Al electrode and the plating film.

Embodiments of a semiconductor device and a method of manufacturing a semiconductor device according to the present disclosure are described in detail with reference to the accompanying drawings. In the description of the embodiments below and the accompanying drawings, main portions that are identical are given the same reference numerals and are not repeatedly described.

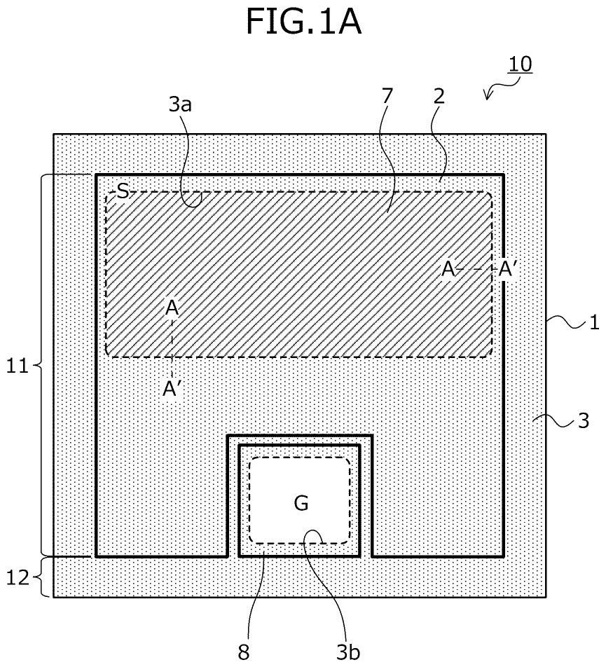

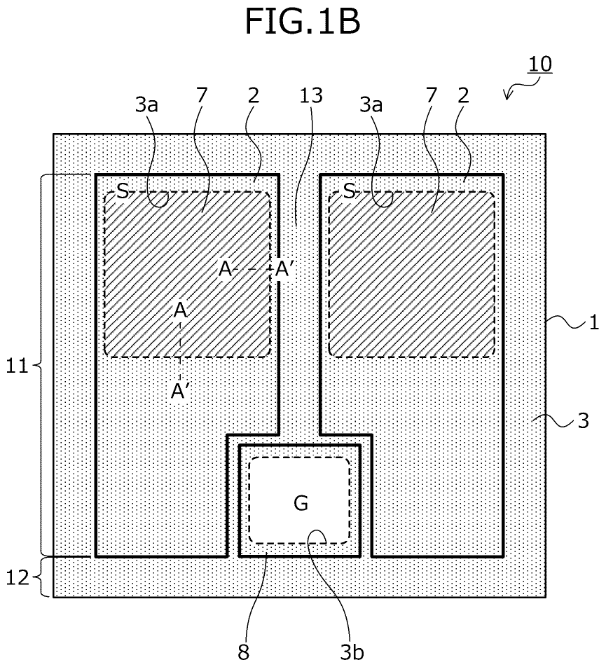

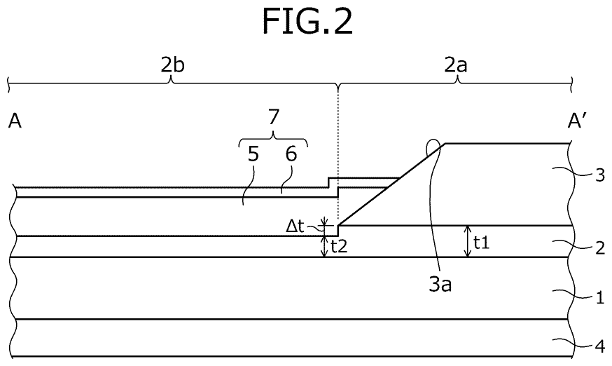

A semiconductor device according to an embodiment solving the above-mentioned problems is described. FIGS. 1A and 1B are plan views depicting examples of layouts of the semiconductor device according to the embodiment, as viewed from a front surface of a semiconductor substrate thereof. FIG. 2 is a cross-sectional view taken along a cutting line A-A′ in FIGS. 1A and 1B. FIGS. 1A and 1B depict examples of layouts of a front electrode 2 when a semiconductor device 10 is a MOSFET. In FIGS. 1A and 1B, a passivation film 3 is indicated by dotted hatching, a plating film 7 is indicated by oblique hatching, the front electrode 2 is indicated by a thick solid line, and outer peripheries of openings 3a and 3b of the passivation film 3 (side surfaces of the passivation film 3) are indicated by dashed lines.

The semiconductor device 10 according to the embodiments depicted in 1A and 2 has a surface electrode (hereinafter, referred to as the front electrode (metal electrode)) 2 on a front surface of a semiconductor substrate (semiconductor chip) 1 in an active region 11 and has a structure in which a surface of a portion (first portion) 2b of the front electrode 2 is covered with the plating film 7 to enhance heat dissipation of the semiconductor substrate 1. As material of the semiconductor substrate 1, Si (silicon) or silicon carbide (SiC) may be used. The active region 11 is a region through which a main current flows when the semiconductor device 10 is on. The active region 11 has, for example, a substantially rectangular shape in a plan view, and is provided in a substantially center (chip center) of the semiconductor substrate 1.

Between the active region 11 and an edge (chip edge) of the semiconductor substrate 1 is an edge termination region 12 surrounding a periphery of the active region 11. The edge termination region 12 has a function of relaxing electric field at the front surface of the semiconductor substrate 1 to maintain a breakdown voltage. In the edge termination region 12, a general breakdown voltage structure (not depicted), such as a field limiting ring (FLR), a junction termination extension (JTE) structure, or a guard ring, is disposed. The breakdown voltage is a limit voltage at which the semiconductor device 10 does not malfunction or break down.

In the active region 11, a predetermined front device element structure (not depicted) is disposed in the semiconductor substrate 1, at the front surface thereof. The front device element structure refers to an insulated gate structure when the semiconductor device 10 is, for example, a metal oxide semiconductor field effect transistor (MOSFET) with an insulated gate consisting of a three-layer structure of metal-oxide-semiconductor) or an insulated gate bipolar transistor (IGBT), and is an anode region when the semiconductor device 10 is a diode.

For example, the IGBT, which is a power semiconductor device, has high-speed switching characteristics and voltage drive suppression of the MOSFET and the low on-voltage characteristics of a bipolar transistor (BJT). As for IGBT structures, a punch-through (PT) type structure, a non-punch-through (NPT) type structure, a field stop (FS) type structure, and the like are known, and the NPT-type and FS-type IGBTs may be fabricated (manufactured), for example, using an inexpensive semiconductor substrate (hereinafter, referred to as FZ wafer) by a floating zone method.

In a case that the semiconductor substrate 1 is, for example, a semiconductor wafer itself such as the FZ wafer, the front device element structure and a back device element structure described later are formed in the semiconductor substrate 1. In a case that the semiconductor substrate 1 is an epitaxial substrate formed by stacking multiple epitaxial layers on a starting substrate (semiconductor substrate), the starting substrate forms the back device element structure, and the front device element structure is formed in the epitaxial layer. By using the semiconductor wafer itself as the semiconductor substrate 1, a thickness of the semiconductor substrate 1 (a product thickness used for the semiconductor device 10) may be made much thinner than using an epitaxial substrate, thereby, enhancing the heat dissipation of the semiconductor substrate 1.

The front electrode 2 is disposed on the front surface of the semiconductor substrate 1 in the active region 11 and is electrically connected to the front device element structure. The front electrode 2 is, for example, an aluminum (Al) film or an Al alloy film such as an aluminum silicon (Al—Si) film. The front electrode 2 has substantially a same shape as that of the active region 11 in a plan view and covers substantially an entire surface of the active region 11 (FIG. 1A). Two front surface electrodes 2 having substantially rectangular shape in a plan view may be arranged apart from each other so as to cover substantially the entire surface of the active region 11 (FIG. 1B). In this case, a portion 13 between the adjacent front surface electrodes 2 may be, for example, a region that does not function as the semiconductor device 10.

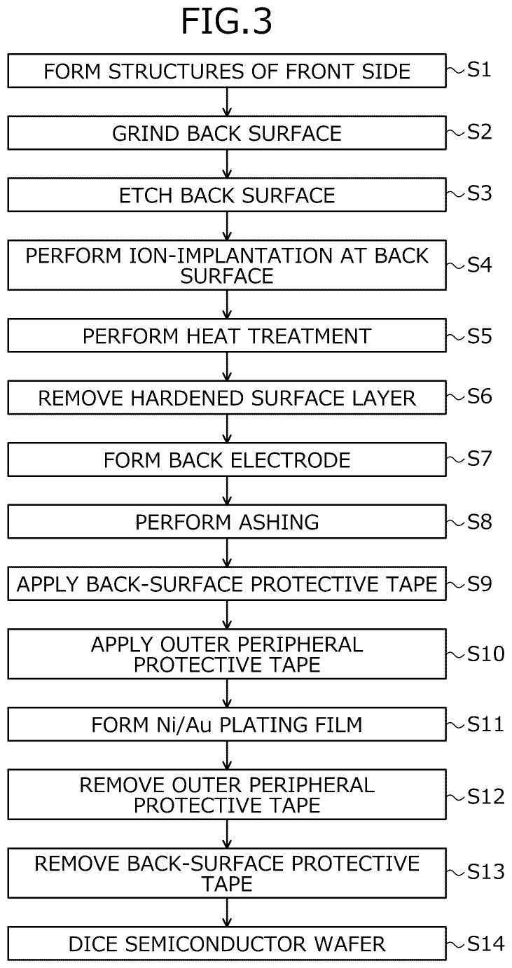

The front electrode 2 is, for example, a source electrode of the MOSFET, an emitter electrode of the IGBT, or an anode electrode of the diode. The front electrode 2 has unevenness (for example, unevenness due to an interlayer insulating film and contact holes thereof) corresponding to the front device element structure. A portion 2b of the front electrode 2 exposed in an opening 3a of the passivation film 3 described later (hereinafter referred to as a pad portion) functions as an electrode pad. On the surface of the front electrode 2, during a process at step S11 (see FIG. 3) described later, the pad portion 2b is etched to be recessed toward a back electrode 4 (back surface of the semiconductor substrate 1) more at the pad portion 2b than at a portion (second portion) 2a covered with the passivation film 3.

That is, a thickness t2 of the pad portion 2b of the front electrode 2 is thinner than a thickness t1 of the portion 2a covered with the passivation film 3 of the front electrode 2. Specifically, a difference Δt (=t1−t2) obtained by subtracting the thickness t2 of the pad portion 2b of the front electrode 2 from the thickness t1 of the portion 2a covered with the passivation film 3 of the front electrode 2 is, for example, about 0.3 μm or more, preferably about 0.4 μm or more, and more preferably about 0.45 μm or more but not more than 0.6 μm. The difference Δt can be detected by observing a cross section of the semiconductor device 10, for example, with a focused ion beam (FIB) device.

When the difference Δt obtained by subtracting the thickness t2 of the pad portion 2b of the front electrode 2 from the thickness t1 of the portion 2a covered with the passivation film 3 of the front electrode 2 is less than the above-mentioned lower limit, the desired adhesion between the front electrode 2 and the plating film 7 is difficult to obtain. The larger the difference Δt is, the higher the desired adhesion between the front electrode 2 and the plating film 7 becomes, but when the difference Δt exceeds the upper limit, the plating film 7 is more likely to have appearance defects at its surface, as described below. By setting the difference Δt within the above range, in conjunction with obtaining the desired adhesion between the front electrode 2 and the plating film 7, surface roughness of the plating film 7 may be suppressed to an extent that semiconductor chips can be automatically recognized.

The thickness t2 of the pad portion 2b of the front electrode 2 is left at least to an extent that the pad portion 2b can maintain a function as the electrode pad. Preferably, the thickness t2 of the pad portion 2b of the front electrode 2 is left to be a thickness that can maintain the heat dissipation of the semiconductor substrate 1. The thickness t1 of the portion 2a covered with the passivation film 3 of the front electrode 2 remains the thickness at the time the front electrode 2 is deposited (processing included in the process at step S1 described later: see FIG. 3), and is, for example, about 5 μm. In the front electrode 2, the portion 2a thereof covered with the passivation film 3 may extend to the edge termination region 12 or to the portion 13 between the adjacent front surface electrodes 2 (FIGS. 1A and 1B).

The passivation film 3 is a protective film (insulating film) made of an organic insulator such as polyimide, is disposed on the top layer of the front surface of the semiconductor substrate 1, and covers almost the entire front surface of the semiconductor substrate 1. The pad portion 2b of the front electrode 2 is exposed in the opening 3a of the passivation film 3. In a case that the semiconductor device 10 is a MOSFET or an IGBT, a gate pad 8 and a gate finger (not depicted) are disposed on the front surface of the semiconductor substrate 1 via an insulating layer (interlayer insulating film, or a stacked film including a field oxide film and the interlayer insulating film, not depicted). For example, the gate pad 8 is exposed in the opening 3b of the passivation film 3 (FIGS. 1A and 1B).

Side walls of the openings 3a and 3b of the passivation film 3 (side surfaces of the passivation film 3) may be perpendicular to the front surface of the semiconductor substrate 1 or may be inclined at a predetermined angle with respect to the front surface of the semiconductor substrate 1 so that the widths of the openings 3a and 3b become wider as with increasing distance from the semiconductor substrate 1. The plating film 7 is disposed on the entire surface of the front electrode 2 (surface of the pad portion 2b of the front electrode 2) at the opening 3a of the passivation film 3. The plating film 7 is formed by stacking a nickel (Ni) plating film 5 and a gold (Au) plating film 6 in this order. Unevenness may occur at the surface of the plating film 7, corresponding to the unevenness of the surface of the front electrode 2.

A predetermined back device element structure is disposed in the semiconductor substrate 1, at the back surface of the semiconductor substrate 1. The back device element structure is, for example, a drain region of a MOSFET, a collector region of an IGBT, or a cathode region of a diode. A surface electrode (hereinafter referred to as the back electrode) 4 is disposed on the entire back surface of the semiconductor substrate 1. The back electrode 4 is electrically connected to the back device element structure. The outermost surface of the back electrode 4 (surface to be bonded to a circuit pattern of a circuit substrate in an assembly process) is preferably formed of a gold (Au) film. The back electrode 4 is, for example, the drain electrode of a MOSFET, the collector electrode of an IGBT, or the cathode electrode of a diode.

A method for manufacturing the semiconductor device according to the embodiment is described. FIG. 3 is a flowchart depicting an outline of the method for manufacturing the semiconductor device according to the embodiment. FIG. 4 is a flowchart depicting an outline of the process at step S11 in FIG. 3. First, structures of a front side of the semiconductor substrate 1 are formed in each chip region (region to become the semiconductor substrate 1), at a front surface (first main surface) of a semiconductor wafer (step S1: first to third steps).

The structures of the front side of the semiconductor substrate 1 refer to the front device element structure (not depicted), the front electrode 2, the insulating layer (not depicted), and the passivation film 3 (moreover, in a case that the semiconductor device 10 is a MOSFET or an IGBT, the gate pad 8 is also included: see FIGS. 1A, 1B, and 2). The chip region is a region that is cut from the semiconductor wafer into individual chips. The openings 3a and 3b may be formed in the passivation film 3 in the process at step S1.

An opening exposing a scribe region (dicing line) may be formed in the passivation film 3. A scribe region is the portion between adjacent chip regions and surrounds the peripheries of the chip regions in a plan view. Between an outermost chip region of the semiconductor wafer and the edge of the semiconductor wafer (wafer edge) is a non-operating region that is not used as the semiconductor chip and for example, in a case where an outer periphery of the semiconductor wafer is formed into a rib shape as described later, the rib portion (outer periphery) is located in the non-operating region.

Thereafter, the semiconductor wafer is ground (back surface grinding) from the back surface (second main surface) to be made thinner to the product thickness used for the semiconductor device 10 (step S2). In the process at step S2, the semiconductor wafer may be a flat plate shape in which the wafer is thinned to the product thickness uniformly over the entire surface or the semiconductor wafer may have the rib shape in which the wafer is thinned to the product thickness only in the center thereof with the outer periphery (wafer outer periphery) remaining thicker than the center by a predetermined width.

When a diameter of the semiconductor wafer exceeds 6 inches, warping of the semiconductor wafer becomes noticeable due to the formation of metal films (front electrode 2, plating film 7, back electrode 4) and a thermal history of temperatures to which the semiconductor wafer is subjected. A strength of the semiconductor wafer may be increased by the rib portion (outer periphery) that is left thick along the outer periphery of the semiconductor wafer. A method for increasing the strength of the semiconductor wafer by forming the rib shape in the outer periphery of the semiconductor wafer is often used particularly in a case where the diameter of the semiconductor wafer is 8 inches or more.

Next, the back surface of the semiconductor wafer is etched (back surface etching) to remove unevenness generated at the back surface of the semiconductor wafer by the back surface grinding at step S2 (step S3). Next, the back device element structure is formed in the semiconductor wafer, at the back surface thereof (step S4) by ion-implanting dopants of a predetermined conductivity type from the back surface of the semiconductor wafer. Thereafter, a heat treatment is performed to electrically activate the dopants ion-implanted in the process at step S4 (step S5).

Thereafter, a hardened layer generated on the surface of the back surface of the semiconductor wafer by the process at step S4 or step S5 is removed (step S6). In a case where the semiconductor wafer is an epitaxial substrate, the starting substrate is the back device element structure, thereby omitting the above-mentioned processes at steps S2 to S6. Next, the back electrode 4 is formed on the entire back surface of the semiconductor wafer by a general method such as vapor deposition or sputtering (step S7).

Next, the plating film 7 is formed by the processes at step S8 to step S13 described later. Specifically, at any timing before the process at step S8, the opening 3a exposing the pad portion 2b of the front electrode 2 is formed in the passivation film 3. Organic residue on the surface of the front electrode 2, at the portion (pad portion 2b) thereof exposed in the opening 3a of the passivation film 3 is removed by ashing (step S8).

Next, a protective tape is applied to a surface of the semiconductor wafer, the surface on which the plating film 7 is not to be formed. For example, the protective tape is applied to the back surface of the semiconductor wafer thereby covering the back electrode 4 with the protective tape (step S9) and then the protective tape is applied to the outer periphery of the semiconductor wafer thereby covering the side surface of the semiconductor wafer with the protective tape (step S10). Then, the semiconductor wafer is inserted into a heat treatment furnace and heated to improve adhesion between the back and side surface of the semiconductor wafer and the protective tapes.

For example, in the semiconductor wafer with a ribbed outer periphery, when the outer periphery of the semiconductor wafer is exposed during the electroless plating treatment, the plating film 7 precipitates easily on the side of the semiconductor wafer. Since the plating film precipitated on the side of the semiconductor wafer becomes a source of foreign matter in the subsequent processes, the process at step S10 is preferably performed. As a method for applying the protective tape to the back and side surface of the semiconductor wafer, for example, a method such as those described in Japanese Laid-Open Patent Publication No. 2011-222898 and Japanese Laid-Open Patent Publication No. 2016-152317 may be used.

Next, the plating film 7 is formed on the pad portion 2b of the front electrode 2 (step S11). As depicted in FIG. 4, in the process at step S11, four pre-treatment steps (pre-treatment for electroless plating treatment) including a cleaner treatment (step S21), etching (step S22: fourth step), pickling (step S23), and a zincate treatment (step S24: fifth step) are carried out in this order and then electroless plating treatment (plating step) at steps S25 and S26 is performed.

The processes at step S21 to step S26 successive processes by a general automated plating equipment and are performed in a series (line) under the same conditions with respect to all the semiconductor wafers in multiple wafer cassettes passing through the line. A water washing treatment (not depicted) is included between each process at step S21 to step S26. The processes at step S21 to step S26 are preferably performed successively with the water washing treatment performed in between and the automated plating equipment may not be used.

The processes at step S21 to S24 are for making the surface of the front electrode 2 at the pad portion 2b thereof in a clean state suitable for the electroless plating treatment. Specifically, the cleaner treatment (degreasing) at step S21 cleans the surface of the pad portion 2b of the front electrode 2 using a surfactant and imparts wettability to the surface of the pad portion 2b with an etching solution in the process at step S22. The cleaner treatment at step S21 is performed, for example, at a temperature of about 50° C. for about 5 minutes.

In conjunction with dissolving (etching) the Al oxide film on the surface of the pad portion 2b of the front electrode 2 with the etching solution, the etching at step S22 adheres metals in the etching solution to the surface of the pad portion 2b, thereby suppressing excessive elution of the pad portion 2b. In conjunction with dissolving the metals adhering to the surface of the pad portion 2b of the front electrode 2, the pickling at step S23 forms a thin Al oxide film with a uniform thickness on the surface of the pad portion 2b.

In conjunction with dissolving (etching) the Al oxide film on the surface of the pad portion 2b of the front electrode 2 with a zincate solution, the zincate treatment at step S24 precipitates a Zn film on the surface of the pad portion 2b by a substitution reaction between Al in the pad portion 2b and zinc (Zn) in the zincate solution. By covering the surface of the pad portion 2b with the Zn film, in conjunction with suppressing surface oxidation of the pad portion 2b, the adhesion of a Ni plating film 5 formed later on the surface of the pad portion 2b is improved.

The Al oxide film on the surface of the pad portion 2b is a stacked film including a thermal oxide film formed by thermal oxidation of the surface of the pad portion 2b due to a temperature distribution between the formation of the front electrode 2 to a process at step S24, and a natural oxide film formed naturally on the surface of the pad portion 2b during transport of the semiconductor wafer or during manufacturing processing at room temperature. The portion 2a of the front electrode 2 covered with the passivation film 3 is neither oxidized nor etched and maintains the thickness t1 when the front electrode 2 was deposited.

In the processes at steps S22 and S24, the pad portion 2b is etched in conjunction with the Al oxide film. Therefore, the thickness t2 of the pad portion 2b becomes thinner than the thickness t1 of the portion 2a of the front electrode 2 covered with the passivation film 3. A total etching amount Dt of the pad portion 2b is the sum of an etching amount of the pad portion 2b by the etching solution in the process at step S22 and an etching amount of the pad portion 2b by the zincate solution in the process at step S24.

In the total etching amount Dt of the pad portion 2b by the processes at steps S22 and S24, etching amounts by the processes at steps S22 and S24 are respectively appropriately set so as to completely remove the Al oxide film formed on the surface of the pad portion 2b with normal thickness variation before or during the substitution reaction between Al and Zn in the zincate treatment at step S24. The total etching amount Dt of the pad portion 2b is obtained in advance.

Specifically, in the processes at steps S22 and S24, the Al oxide film on the surface of the pad portion 2b is etched to be removed by the maximum thickness within a range of normal thickness variation of the Al oxide film obtained in advance for each surface layer of the pad portion 2b. In other words, regardless of the actual thickness of the Al oxide film on the surface of the pad portion 2b, the total etching amount Dt of the pad portion 2b is set so that the Al oxide film on the surface of the pad portion 2b is removed with the maximum thickness that can be assumed for the Al oxide film.

The normal thickness variation of the Al oxide film on the surface of the pad portion 2b refers to thickness variation occurring in the Al oxide film formed on the surface of the pad portion 2b during a normal manufacturing process or during transport of the semiconductor wafer which are performed between the formation of the front electrode 2 and the process at step S24, and excludes abnormal values and outliers. Normal thickness variation of the Al oxide film also occurs, for example, when the Al oxide film is formed so as to fill in the unevenness occurring at the surface of the front electrode 2.

More specifically, the total etching amount Dt of the pad portion 2b by the processes at steps S22 and S24 is about 0.3 μm or more, preferably about 0.4 μm or more, and more preferably about 0.45 μm or more but not more than 0.6 μm. Namely, the total etching amount Dt of the pad portion 2b corresponds to the difference Δt obtained by subtracting the thickness t2 of the pad portion 2b of the front electrode 2 from the thickness t1 of the portion 2a of the front electrode 2 covered with the passivation film 3.

In the processes at steps S22 and S24, the total etching amount Dt of the pad portion 2b is set within the above range, whereby the Al oxide film formed on the pad portion 2b surface with the normal thickness variation is completely removed with the surface layer of the pad portion 2b. Thus, a clean surface is exposed in an entire area of the surface of the pad portion 2b and the zincate treatment is performed normally on the entire exposed surface (clean surface) of the pad portion 2b to precipitate the Zn film.

The total etching amount Dt of the pad portion 2b by the processes at steps S22 and S24 is preferably adjusted by, for example, an etching amount of the pad portion 2b by the etching solution of the etching at step S22. For example, as zincate treatment conditions at step S24, existing conditions (for example, generally recommended zincate treatment conditions) under which the zincate treatment has been confirmed to be operated normally may be applied.

A reason is that a specific problem is likely to occur when the zincate treatment conditions at step S24 are changed even slightly. For example, while the etching amount of the pad portion 2b may be increased by tightening the zincate treatment conditions at step S24, there is a risk of a shortened life of the zincate solution, appearance defects of the plating film 7 surface due to surface roughness of the pad portion 2b, excessive occurrence of spikes (long and narrow grooves in the depth direction) on the pad portion 2b surface, and the like.

An appearance defect of the plating film surface is, for example, the unevenness (surface roughness) occurring at the surface of the plating film 7 corresponding to unevenness of the surface of the pad portion 2b. When the unevenness of the plating film 7 surface causes excessive light diffused reflection, there is a risk that image recognition on the semiconductor chip (semiconductor substrate 1) cannot be performed in the semiconductor manufacturing device. When excessive spikes occur at the surface of the pad portion 2b, sides of multiple spikes are connected to each other and adhesion between the pad portion 2b and the plating film 7 is reduced at the connection points of the spikes.

Making the zincate treatment conditions at step S24 stricter means, for example, performing the zincate treatment excessively by such as increasing the alkali concentration or temperature of the zincate solution and by lengthening zincate treatment time. Whereas, if the zincate treatment conditions are eased (by lowering the alkali concentration or temperature of the zincate solution, or by shortening the zincate treatment time), the etching amount of the pad portion 2b is reduced, or an action of the zincate treatment is suppressed.

When the zincate treatment conditions at step S24 are eased, the occurrence of spikes at the surface of the pad portion 2b can be suppressed, but the zincate treatment is performed in a state where the Al oxide film remains locally on the surface of the pad portion 2b. In the zincate treatment at step S24, extreme lowering of the alkali concentration of the zincate solution or extreme shortening of the zincate treatment time are not appropriate, compared to the recommended conditions for general zincate treatment.

For example, the inventors of the present invention experimented with the zincate treatment at step S24 under the generally recommended conditions and found that the etching amount of the pad portion 2b was about 0.2 μm. Therefore, the inventors set the etching amount of the pad portion 2b by the zincate treatment at step S24 to about 0.2 μm and performed the electroless plating treatment at steps S25 and S26 described below on two samples with different etching amounts of the pad portion 2b by the etching at step S22.

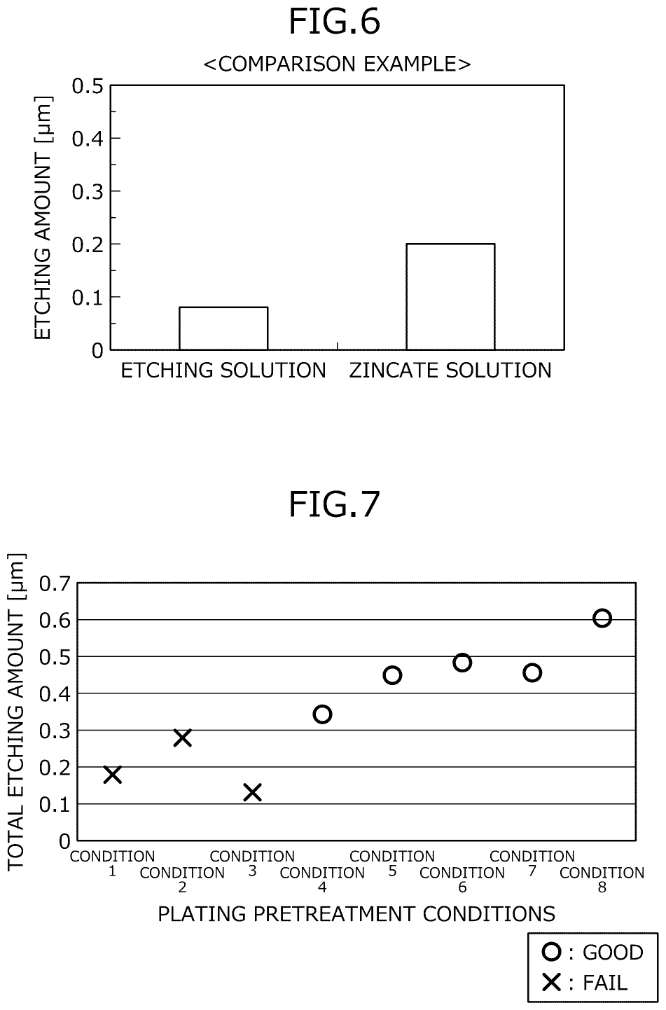

For each of these two samples (hereinafter referred to as example and comparison example), the etching amounts of the pad portion 2b by the etching solution (etching at step S22) and the zincate solution (zincate treatment at step S24) used in the pre-treatment for the electroless plating treatment are depicted in FIGS. 5 and 6. FIGS. 5 and 6 are graphs depicting the etching amount of the Al electrode (pad portion 2b of the front electrode 2) by the pre-treatment for the electroless plating treatment in the example and the comparison example, respectively.

The example corresponds to a sample of a plating pretreatment condition 5 of a study example described later (see FIG. 7), and the etching amount of the pad portion 2b by the etching at step S22 is about 0.29 μm (FIG. 5), the etching amount of the pad portion 2b by the etching at step S22 is increased compared to the comparison example, and the total etching amount Dt of the pad portion 2b by the processes at steps S22 and S24 is about 0.49 μm, within the above-mentioned range.

The comparison example corresponds to a sample of a plating pretreatment condition 2 of the study example described later (see FIG. 7), and the etching at step S22 is performed under the generally recommended conditions, and the etching amount of the pad portion 2b by the etching at step S22 is about 0.08 μm (FIG. 6). In the comparison example, the total etching amount Dt of the pad portion 2b by the processes at steps S22 and S24 was about 0.28 μm, outside the above-mentioned range.

As described later, peeling of the plating film 7 occurred in the comparison example, but not in the example. As described, the adhesion between the pad portion 2b and the plating film 7 can be improved by increasing only the etching amount of the pad portion 2b by the etching at step S22 so that the total etching amount Dt of the pad portion 2b by the processes at steps S22 and S24 is within the above-mentioned range.

The etching amount of the pad portion 2b by the etching at step S22 may be the same as or greater than that of the pad portion 2b by the zincate treatment at step S24. The more the etching amount of the pad portion 2b by the etching at step S22 increases, the more the etching amount of the pad portion 2b by the zincate treatment at step S24 can be reduced, and zincate solution conditions for the zincate treatment may be provided a margin.

The etching amount of the pad portion 2b by the etching at step S22 may be adjusted by increasing a concentration or temperature of the etching solution or by increasing the etching time. For example, an etching amount after a change in conditions becomes easier to estimate from a tendency of the etching amount of the pad portion 2b under the existing conditions by changing one of the existing conditions for the etching at step S22 (for example, increasing only the etching time).

As described, the Zn film can be precipitated on the entire surface of the pad portion 2b by the pre-treatment for the electroless plating treatment. The electroless Ni plating treatment is performed on the surface of this pad portion 2b (step S25). In the electroless Ni plating treatment at step S25, the Zn film contacts a plating solution containing Ni which is a metal more valuable than Zn, precipitating the Ni plating film 5 on the surface of the pad portion 2b by an autocatalytic reaction of Ni substituted for Zn.

Thereafter, an electroless Au plating treatment is performed on the surface of the Ni plating film 5 under general conditions (step S26). In the electroless Au plating treatment at step S26, Ni in the Ni plating film 5 dissolves and an Au plating film 6 precipitates on the surface of the Ni plating film 5 (outermost surface of the pad portion 2b). In conjunction with preventing oxidation of the surface of the Ni plating film 5, the Au plating film 6 imparts solder wettability to the Ni plating film 5 surface.

By the electroless plating treatment at steps S25 and S26 described above, a plating film 7 is formed on the surface of the pad portion 2b, plating film 7 being formed by precipitating the Ni plating film 5 and the Au plating film 6 in this order. A thickness of the Au plating film 6 is extremely thin to an extent that the thickness thereof cannot be confirmed by, for example, an FIB device. Thus, the plating film 7 consisting of the Ni plating film 5 and the Au plating film 6 is sometimes collectively referred to as a Ni/Au plating film.

Next, the protective tape is peeled off from the side surface of the semiconductor substrate 1 using an existing tape peeling method (step S12). Next, the protective tape is peeled off from the back surface of the semiconductor substrate 1 using the existing tape peeling method (step S13). Then, after performing an electrical test in a state of the semiconductor wafer, the semiconductor wafer is diced (cut) along the scribe regions thereby separating the chip regions into individual chips (step S14) and thus, completing the semiconductor device 10 (semiconductor chip).

During the subsequent assembly steps (semiconductor chip mounting step), a bonding wire is bonded to the pad portion 2b of the semiconductor device 10 via the plating film 7.

As described, according to the embodiment, the etching amount of the Al electrode in the pre-treatment for the electroless plating treatment of the Al electrode (electrode containing Al) is set in advance, completely etching, for each surface layer of the Al electrode, the Al oxide film that is at the surface of the Al electrode and within a range of normal thickness variation, before starting the substitution reaction between Al in the Al electrode and Zn in the zincate solution or during the substitution reaction. Thus, a clean surface is exposed in the entire area of the surface of the Al electrode and the zincate treatment is performed normally on the entire exposed surface (clean surface) of the Al electrode and the Zn film is precipitated. Thus, in conjunction with ensuring the adhesion between the Al electrode and the Ni plating film in the subsequent electroless Ni plating treatment, dissolution of the pad portion by the plating solution of the electroless Ni plating treatment may be suppressed, thereby improving reliability of the semiconductor device.

According to the embodiment, a total etching amount of the etching amount of the Al electrode by the etching solution in the etching and the etching amount of the Al electrode by the zincate solution in the zincate treatment may be set appropriately and is easily applicable to existing manufacturing processes. Even with the zincate solution which etches more gently than the etching solution, a locally thick portion of the Al oxide film on the surface of the Al electrode can be removed, thereby suppressing peeling of the plating film from the Al electrode due to residual Al oxide film on the surface of the Al electrode. According to the embodiment, the Al electrode is etched using the zincate solution, thereby suppressing the occurrence of spikes on the surface of the Al electrode. As a result, the peeling of the plating film caused by spikes at the interface between the Al electrode and the plating film is suppressed, further improving the reliability of the semiconductor device.

According to the embodiment, the total etching amount of the Al electrode may be appropriately set, so that surface roughness of the Al electrode may be suppressed. Thus, even when a plating film is plated to a chip, appearance defects of the plating film surface caused by the surface roughness of the Al electrode may be suppressed. According to the embodiment, in adjusting the total etching amount of the Al electrode in the pre-treatment for the electroless plating treatment of the Al electrode, the etching amount of the Al electrode by the etching solution in the etching is increased as much as possible to an extent that appearance defects of the plating film surface due to the surface roughness of the Al electrode do not occur, thereby allowing the condition of the zincate solution in the zincate treatment to have a margin. This allows suppression of the occurrence of spikes at the surface of the Al electrode caused by performing the zincate treatment excessively.

The semiconductor chip (semiconductor device 10) was fabricated according to a method for manufacturing the semiconductor device according to the embodiment (see FIG. 4), and a relationship between the total etching amount Dt of the pad portion 2b by the processes at steps S22 and S24 and the adhesion between the pad portion 2b and the plating film 7 was verified, results thereof are depicted in FIG. 7. FIG. 7 is a graph depicting results of an experiment on a relationship between pre-treatment conditions (plating pretreatment conditions) of the electroless plating treatment and the total etching amount of the Al electrode (pad portion 2b of the front electrode 2).

Plating pretreatment conditions 1 to 8 in FIG. 7 differ only in the process conditions at steps S22 and S24. The adhesion between the pad portion 2b and the plating film 7 was confirmed by a tensile test for multiple semiconductor chips in conjunction with each of the plating pretreatment conditions 1 to 8. “Good” indicated by a circle in FIG. 7 means that no peeling of the plating film 7 from the pad portion 2b occurred in any of the semiconductor chips. “Fail” indicated by an X in FIG. 7 means that the plating film 7 peeled off from the pad portion 2b in at least one semiconductor chip.

As depicted in FIG. 7, in the sample of the plating pretreatment condition 2, the etching amount of the pad portion 2b by the etching solution was 0.08 μm and the etching amount of the pad portion 2b by the zincate solution was about 0.2 μm. In the sample of the plating pretreatment condition 2, the total etching amount Dt of the pad portion 2b was about 0.28 μm and the plating film 7 peeled off at the interface between the pad portion 2b and the plating film 7. Even with the conditions 1 and 3 in which the total etching amount Dt of the pad portion 2b was smaller than that of the sample of the plating pretreatment condition 2, the plating film 7 peeled off at the interface between the pad portion 2b and the plating film 7.

On the other hand, in the samples of the plating pretreatment conditions 4 to 8, peeling of the plating film 7 did not occur and no appearance defects, such as surface roughness, occurred at the surface of the plating film 7. By making the total etching amount Dt of the pad portion 2b by the processes at steps S22 and S24 larger than the sample of the plating pretreatment condition 2, the peeling of the plating film 7 and appearance defects such as the surface roughness are together assumed not to occur. The inventors empirically found that the total etching amount Dt of the pad portion 2b by the processes at steps S22 and S24, the total etching amount Dt that provides the above-mentioned effect, is about 0.3 μm or more.

The sample under the plating pretreatment condition 6 has the same zincate treatment conditions at step S24 as those under the plating pretreatment condition 2, but the etching time of the etching at step S22 is three times longer than that under the plating pretreatment condition 2, thereby increasing the total etching amount Dt of the pad portion 2b to about 0.49 μm. In a case where the zincate treatment conditions at step S24 are fixed and the etching conditions at step S22 are changed as described, the effects of the embodiment are confirmed to be obtained.

In the foregoing, the present disclosure is not limited to the embodiments described and various modifications within the scope of the present disclosure are possible. For example, the zincate treatment on the front surface electrode may be performed twice (double zincate treatment). The front electrode is not limited to an electrode containing Al and may be mainly composed of another base metal less noble (with a greater ionization tendency) than Zn in the zincate solution. The plating film on the surface of the front surface electrode is not limited to a Ni/Au plating film and may be a plating film of other metals more noble (with a smaller ionization tendency) than Zn in the zincate solution. According to the semiconductor device and the method for

manufacturing the semiconductor device of the present disclosure, reliability of the semiconductor device can be improved.

As described above, the semiconductor device and the method for manufacturing a semiconductor device according to the present disclosure are useful for semiconductor devices in which bonding wires are bonded to front electrodes via plating films.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a semiconductor device, the method comprising:
preparing a semiconductor substrate having a first main surface and a second main surface opposite to each other;
forming a metal electrode on the first main surface of the semiconductor substrate, the metal electrode having a first portion and a second portion, the first portion having a surface layer and an oxide film formed on the surface layer;
forming an insulating film to cover the metal electrode;
forming an opening penetrating through the insulating film in a depth direction, to thereby expose the first portion of the metal electrode;
performing a pre-treatment of removing the oxide film of the first portion; and
performing an electroless plating treatment after the pre-treatment, to thereby form a plating film on the first portion, wherein
the second portion is covered with the insulating film,
the pre-treatment includes etching the first portion by a predetermined etching amount, to thereby remove the oxide film together with the surface layer, so as to cause a thickness of the first portion to be thinner than a thickness of the second portion, and
the surface layer of the first portion has a maximum thickness that is within a range of thickness variation of the oxide film.

2. The method of manufacturing a semiconductor device according to claim 1, wherein
the metal electrode contains a first metal;
the pre-treatment includes:
etching the oxide film, for a first etching amount, with an etching solution; and
subsequently etching the oxide film, for a second etching amount, with a zincate solution to precipitate a second metal on the first portion, the second metal having a smaller ionization tendency than the first metal; and
the predetermined etching amount is a sum of the first etching amount and the second etching amount.

3. The method of manufacturing a semiconductor device according to claim 2, wherein the first etching amount is equal to or greater than the second etching amount.

4. The method of manufacturing a semiconductor device according to claim 1, wherein the predetermined etching amount is 0.3 μm or more but not more than 0.6 μm.

5. The method of manufacturing a semiconductor device according to claim 4, wherein the predetermined etching amount is 0.4 μm or more.

6. The method of manufacturing a semiconductor device according to claim 5, wherein the predetermined etching amount is 0.45 μm or more.

7. The method of manufacturing a semiconductor device according to claim 1, wherein
the forming the metal electrode includes forming an aluminum film or an aluminum alloy film as the metal electrode, and
the performing an electroless plating treatment includes forming a nickel-plating film as the plating film, the nickel-plating film being in contact with at least the first portion.

8. A semiconductor device comprising:
a semiconductor substrate having a first main surface and a second main surface opposite to each other;
a metal electrode provided on the first main surface of the semiconductor substrate, the metal electrode having a first portion and a second portion;
an insulating film having an opening penetrating therethrough in a depth direction, the insulating film covering the second portion of the metal electrode, and exposing the first portion of the metal electrode through the opening; and
a plating film provided on a surface of the first portion, wherein
the first portion of the metal electrode is recessed towards the second main surface of the semiconductor substrate, and
a difference between a thickness of the first portion and a thickness of the second portion is 0.3 μm or more but not more than 0.6 μm.

9. The semiconductor device according to claim 8, wherein the difference is 0.4 μm or more.

10. The semiconductor device according to claim 9, wherein the difference is 0.45 μm or more.

11. The semiconductor device according to claim 8, wherein
the metal electrode is an aluminum film or an aluminum alloy film, and
the plating film has a nickel-plating film in contact with at least the first portion.
